(19) United States
(12) Patent Application Publication
(10) Pub. No.: US 2017/0278994 A1
(43) Pub. Date: Sep. 28, 2017

(54) COLOR TUNABLE THIN FILM PHOTOVOLTAIC DEVICES

(71) Applicant: International Business Machines Corporation, Armonk, NY (US)

(72) Inventor: Richard A. Haight, Mahopac, NY (US)

(21) Appl. No.: 15/077,996

(22) Filed: Mar. 23, 2016

(51) Int. Cl. H01L 31/054

(52) U.S. Cl. CPC H01L 31/054

(57) ABSTRACT

A method of fabricating a color tunable thin film photovoltaic device includes depositing a layer of a semiconducting compound configured to exhibit a photovoltaic effect, and depositing a buffer layer over the layer of the semiconducting compound. Depositing transparent conducting oxides (TCO) over the buffer layer is followed by selecting two or more layers of optically transparent materials such that constructive interference among wavelengths reflected by the buffer layer, the TCO, and the two or more layers results in a desired exhibited color and depositing the two or more layers of the optically transparent materials above the TCO.

### BACKGROUND

The present invention relates to photovoltaic devices, and more specifically, to color tunable thin film photovoltaic devices.

Photovoltaic devices include semiconducting materials that exhibit the photovoltaic effect. The photovoltaic effect is a process by which electricity is generated based directly on exposure to light. Photovoltaic systems (e.g., solar panels) supply usable electrical energy and are increasingly used as alternatives to traditional fossil fuel-based energy sources. While many conventional energy sources are provided to consumers over a grid structure from a central location, photovoltaic systems may be used to generate electricity at the point of use. Thin film photovoltaic devices may be incorporated into building exteriors, for example. These devices may be used for large scale electrical generation to partly or completely power the building. Some of the power generated using photovoltaic devices may even be sold back to the conventional grid-based power generation utility. Photovoltaic devices may also be used in low light situations, such as inside a structure, to power switches or sensors. In both indoor and outdoor installations, photovoltaic devices that use non-toxic and earth abundant (i.e., readily available) semiconductor materials are of interest.

### SUMMARY

According to an embodiment of the present invention, a method of fabricating a color tunable thin film photovoltaic device includes depositing a layer of a semiconducting compound configured to exhibit a photovoltaic effect; depositing a buffer layer over the layer of the semiconducting compound; depositing transparent conducting oxides (TCO) over the buffer layer; selecting two or more layers of optically transparent materials such that constructive interference among wavelengths reflected by the buffer layer, the TCO, and the two or more layers results in a desired exhibited color; and depositing the two or more layers of the optically transparent materials above the TCO.

According to another embodiment, a color tunable thin film photovoltaic device includes a layer of a semiconducting compound that exhibits a photovoltaic effect; a buffer layer on the semiconducting compound, the buffer layer forming a p-n junction with the semiconducting compound; transparent conducting oxides (TCO) on the buffer layer; and two or more layers of optically transparent materials configured to control an exhibited color of the photovoltaic device, the two or more layers being selected such that constructive interference among wavelengths reflected by the buffer layer, the TCO, and the two or more layers results in the exhibited color.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIGS. 1-3 show cross-sectional views of intermediate structures involved in the fabrication of a photovoltaic device according to embodiments, in which:

FIG. 1 shows an intermediate structure including the photovoltaic film;

FIG. 2 results from deposition of a buffer layer and transparent conducting oxides;

FIG. 3 shows the result of forming metal lines;

FIG. 4 shows a cross-sectional view of the color tunable thin film photovoltaic device according to embodiments;

FIG. 5 is a cross-sectional view of an exemplary photovoltaic device according to an embodiment; and

FIG. 6 is a cross-sectional view of an exemplary photovoltaic device according to another embodiment.

### DETAILED DESCRIPTION

Various embodiments of the present disclosure are described herein with reference to the related drawings. Alternative embodiments may be devised without departing from the scope of this disclosure. It is noted that various connections and positional relationships (e.g., over, below, adjacent, etc.) are set forth between elements in the following description and in the drawings. These connections and/or positional relationships, unless specified otherwise, may be direct or indirect, and the present disclosure is not intended to be limiting in this respect. Accordingly, a coupling of entities may refer to either a direct or an indirect coupling, and a positional relationship between entities may be a direct or indirect positional relationship. As an example of an indirect positional relationship, references in the present disclosure to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

For the sake of brevity, conventional techniques related to semiconductor device and IC fabrication may not be described in detail herein. Moreover, the various tasks and process steps described herein may be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

As previously noted herein, photovoltaic devices are increasingly used as an alternate means of on-site power generation. Thin film photovoltaic devices may be installed outside or within structures to generate power directly from light. These photovoltaic devices must be exposed in order to easily receive the light needed to generate electricity. Yet, the exposure of the photovoltaic devices makes them conspicuous and may detract from the architectural or aesthetic features on the exterior or interior of a building. The concerns about appearance may reduce the appeal of photovoltaic devices as power generation alternatives.

A known approach to reducing the negative aesthetic or architectural impact of photovoltaic devices involves fabricating the photovoltaic films with a sufficiently small thickness so that the appearance of the underlying structure (e.g., wall, tile) is visible. However, this approach may present several issues. The color of the underlying structure may be skewed to a red shade because of the wavelengths that are able to penetrate the farthest in typical photovoltaic absorber materials with a 1 to 1.5 electron-volt (eV) band gap. The band gap indicates the energy difference between the top of the valence band and the bottom of the conduction band or an energy range in which no electron states can exist. In addition, decreased efficiency may result from partial absorption of the incident light or shunting (low resistance across the device), which is common in ultrathin photovoltaic devices.

Another known approach to reducing the negative aesthetic or architectural impact of photovoltaic devices involves locating the photovoltaic devices in a pattern that leaves open areas through which significant portions of the building structure remain visible. However, with fewer photovoltaic devices that can receive the available light, efficiency drops.

Turning now to an overview of the present disclosure, one or more embodiments provide fabrication methodologies and resulting structures for tuning the color of a thin-film photovoltaic device. More specifically, one or more embodiments of the systems and methods detailed herein control the color and/or two-dimensional characteristics exhibited by photovoltaic devices so that they blend in with or enhance the decorative aspects of the underlying structure on which they are arranged. According to one or more embodiments, the color and/or decorative properties of a photovoltaic device are controlled by controlling the top transparent layers that may be used as anti-reflection (AR) coatings in a photovoltaic device. When the top transparent layers act as AR coatings, the thicknesses of the full stack of dielectrics including the buffer and absorber below the transparent layers are optimized to minimize reflection of light that is incident on the device. The transparent layers are composed of alternating layers of MgF₂ and SiO₂ or similar pairs of materials with differing indices of refraction. To achieve reflectance of a single color of light (narrow band of wavelengths centered on the desired reflected color), the transparent layers work in conjunction with the transparent conducting oxide (TCO) layers, the n-type buffer layer (typically CdS), and the photovoltaic film layer to produce the color exhibited by the device. Thus, materials for the transparent layers are selected such that constructive interference among wavelengths reflected by all the layers of the device results in the desired exhibited color. Colors can be patterned by varying the thickness of the transparent layers.

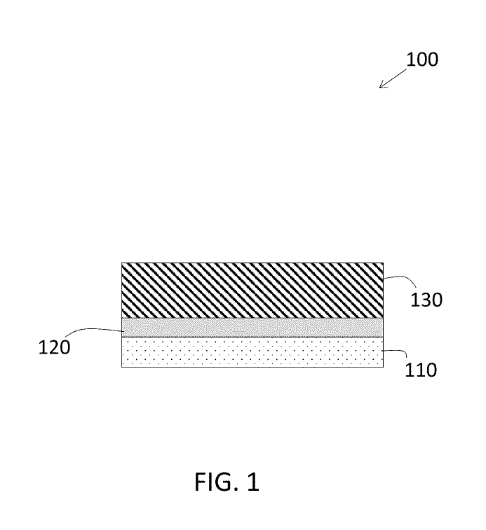

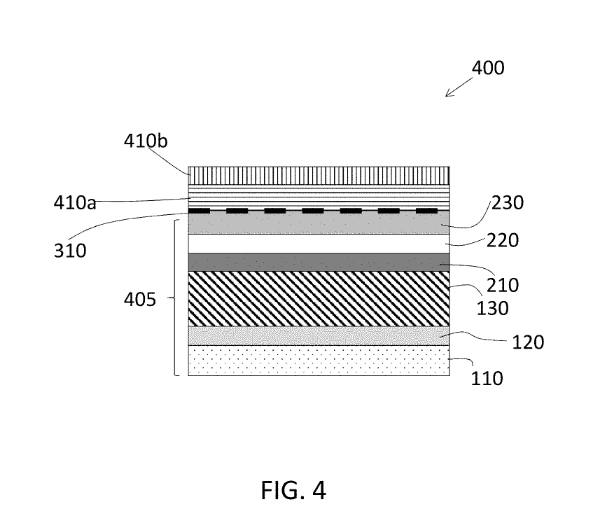

Turning now to a more detailed description of one or more embodiments, FIGS. 1-3 show cross-sectional views of intermediate structures involved in the fabrication of a photovoltaic device 400 (FIG. 4) according to embodiments of the invention. FIG. 1 shows an intermediate structure 100 that includes a photovoltaic film 130. The photovoltaic film 130 may be an absorber that is an earth abundant semiconducting compound. Exemplary photovoltaic films 130 include copper-zinc-tin-sulfide (CZTS), copper-zinc-tin-selenium (CZT Se), selenium (Se), copper-zinc-tin-sulfur-selenium (Cu_{z}ZnSn(SₓSe₁₋ₓ)₄), and alloys of copper and silver Ag such as AgCZTSe and AgZTSe. Among the exemplary photovoltaic films 130, all but AgZTSe are p-type materials. AgZTSe is an n-type material. The photovoltaic film 130 may be deposited by vacuum or solution techniques on a molybdenum (Mo) layer 120. The photovoltaic film 130 may be polished by a chemical-mechanical planarization (CMP) process. The Mo layer 120 may have a thickness on the order of 700 nanometers (nm), for example. The Mo layer 120 is formed on a layer of soda-lime glass 110 or silica glass. The soda-lime glass 110 and Mo layer 120 together form an opaque substrate. Based on the placement of the photovoltaic device 400, the substrate may be a portion of the structure. For example, when the photovoltaic device 400 is used on the exterior of a tiled building, the tiles may act as the substrate. The photovoltaic film 130 is assumed to be sufficiently absorptive such that reflections from the substrate need not be considered in controlling the exhibited color. According to one or more embodiments, the reflectivity of the photovoltaic film 130 may be considered. The index of refraction (or refractive index) of CZTS, for example, is 2.85.

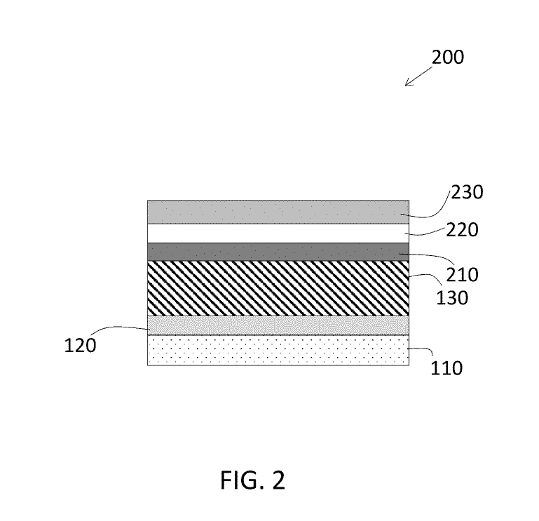

FIG. 2 shows an intermediate structure 200 that results from deposition of a buffer layer 210 and transparent conducting oxide (TCO) layers 220, 230. The buffer layer 210 is an electrical and optical layer. The buffer layer 210 may be comprised of an n-type material such as cadmium sulfide (CdS), for example. CdS appears yellow and has a band gap of 2.4 eV. CdS has a refractive index that decreases as the wavelength of incident light increases. For example, the refractive index of CdS is 2.0 at 400 nm and 1.6 at 800 nm. The buffer layer 210 may instead be comprised of an p-type material such as copper oxide (Cu2O) or zinc telluride (ZnTe), for example. When the photovoltaic film 130 is an p-type material and the buffer layer 210 is a n-type material or when the photovoltaic film 130 is an n-type material and the buffer layer 210 is a p-type material, a p-n junction is formed by the deposition of the buffer layer 210 over the photovoltaic film 130. The buffer layer 210 may have a thickness on the order of 25-50 nm. The TCO layers 220, 230 deposited on the buffer layer 210 may be comprised of a zinc oxide (ZnO) layer 220 and an Indium tin oxide (ITO) layer 230. The TCO layers 220, 230 are part of the optical stack. The refractive index of ZnO is 2.0 over a wide range of incident wavelengths, but the refractive index of ITO decreases with the wavelength of incident light. For example, the refractive index of ITO is 2.0 at 400 nm and 1.6 at 800 nm.

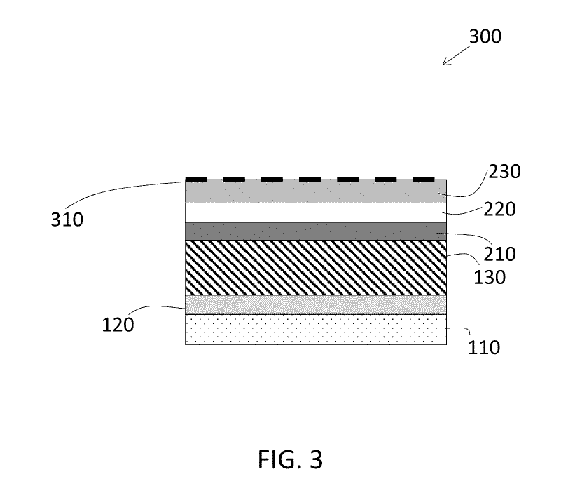

FIG. 3 shows the addition of metal lines 310 above the TCO layers 220, 230 to result in an intermediate structure 300. For ease of illustration and reference, only one metal line 310 shown in FIG. 3 is provided with a reference number. The buffer layer 210 and TCO layers 220, 230 are conductive layers that transport electrons generated by the photovoltaic film 130 to the metal lines 310 so that collected direct current may be obtained from the photovoltaic device 400 (FIG. 4). The metal lines 310 may be comprised of aluminum (Al) or nickel aluminum (NiAl), for example.

FIG. 4 shows a cross-sectional view of the color tunable thin film photovoltaic device 400 according to embodiments of the invention. The previously discussed layers (soda-lime glass 110, Mo layer 120, photovoltaic film 130, buffer layer 210, and TCO layers 220, 230) are collectively labelled as base layers 405 in FIG. 4. The photovoltaic device 400 includes optically transparent layers 410a, 410b (generally 410) above the metal lines 310. Optically transparent refers to the fact that the layers 410 pass nearly all the incident light into the base layers 405 for use by the photovoltaic film 130. As such, the layers 410 act predominantly as an anti-reflective (AR) coating. The optically transparent layers 410 reflect only a narrow band of wavelengths associated with colors of interest. The layers 410a, 410b have different indexes of refraction, and the wavelengths reflected by each layer 410a, 410b constructively interfere to define the color that is exhibited.

More specifically, the layers 410a, 410b are selected in consideration of constructive interference among reflected wavelengths not only of the layers 410a, 410b but also of the TCO layers 220, 230, buffer layer 210, and photovoltaic film 130, because the exhibited color of the photovoltaic device 400 is a result of constructive interference of reflected wavelengths from all these layers, as further discussed below. The layers 410 are color tunable because the ranges of wavelengths that are ultimately exhibited by the photovoltaic device 400 may be controlled based on the selection of the layers 410 and their thicknesses. Both the materials chosen for each of the layers 410 and the thickness of each of the layers 410 affect the exhibited color. Reflectance and thickness have a linear relationship such that a change in thickness of one of the layers 410 has a proportional effect on reflectance of that layer.

Because the layers 410 act predominantly as an AR coating, they work in conjunction with the buffer layer 210 and the TCO layers 220, 230 to maximize the light that reaches the photovoltaic film 130 for conversion to direct current. In this regard, the layers 410 represent a departure from the above-noted previous approaches to addressing the aesthetic aspect of photovoltaic devices 400 that reduce the efficiency of the photovoltaic devices 400.

Exemplary materials that may be used as layers 410a, 410b are shown below in Table 1. Materials in two ranges of index of refraction values are shown. If layer 410a is selected from one index of refraction column (e.g., n<1.6), then layer 410b is selected from the other index of refraction column (1.6<n<1.8). The wavelength (of incident light) corresponding with the index of refraction values is also indicated, because refractive index is not constant over all wavelengths for most of the materials. For example, as Table 1 indicates, the refractive index of MgF₂ is below 1.6 only up to a wavelength of 1100 nm, while the refractive index of YF₃ is below 1.6 only above a 5,000 nm wavelength..

TABLE 1
Exemplary materials for layers 410.

| Wavelength | | |
|---|---|---|
| range (nm) | n < 1.6 | 1.6 < n < 1.8 |
| 250-400 | magnesium fluoride (MgF₂) | aluminum oxide (Al₂O₃) |
| | silicon dioxide (SiO₂) | yttrium oxide (Y₂O₃) |
| | cerium fluoride (CeF₃) | |
| 400-1100 | magnesium fluoride (MgF₂) | aluminum oxide (Al₂O₃) |
| | silicon dioxide (SiO₂) | yttrium oxide (Y₂O₃) |
| 1100-5,000 | silicon dioxide (SiO₂) | aluminum oxide (Al₂O₃) |
| | cerium fluoride (CeF₃) | yttrium oxide (Y₂O₃) |
| 5,000-12,000 | cerium fluoride (CeF₃) | — |
| | yttrium fluoride (YF₃) | |
| | thorium tetrafluoride (ThF₄) | |

Although two layers 410a, 410b are shown for the exemplary embodiment in FIG. 4, additional layers may be added according to alternate embodiments. The additional layers 410 may be selected from Table 1 such that adjacent layers 410 are selected from different columns (adjacent layers 410 have different indexes of refraction).

As noted above, the reflected light due to each of the layers 410 constructively interferes with reflected light due to the TCO layers 220, 230, buffer layer 210, and photovoltaic film 130 to exhibit a particular color. Thus, to obtain a desired exhibited color, materials and thicknesses may be selected for two or more layers 410. The determination of thicknesses and materials (based on their corresponding refractive indexes) for the two or more layers 410 to obtain the desired exhibited color is not straight-forward and may be achieved according to the teachings of the present disclosure by using well-known models. These known models provide reflectance response resulting from multiple layers as a function of the refractive index of each of the layers and impedance at each interface of layers, which is a function of the thickness of each layer. For a given photovoltaic device 400, the materials and their thicknesses are known for the TCO layers 220, 230, buffer layer 210, and photovoltaic film 130. The reflected wavelength that is ultimately desired (the exhibited color) is also known. These known values may be used in conjunction with the known models to define and solve for the layers 410 as the unknown values.

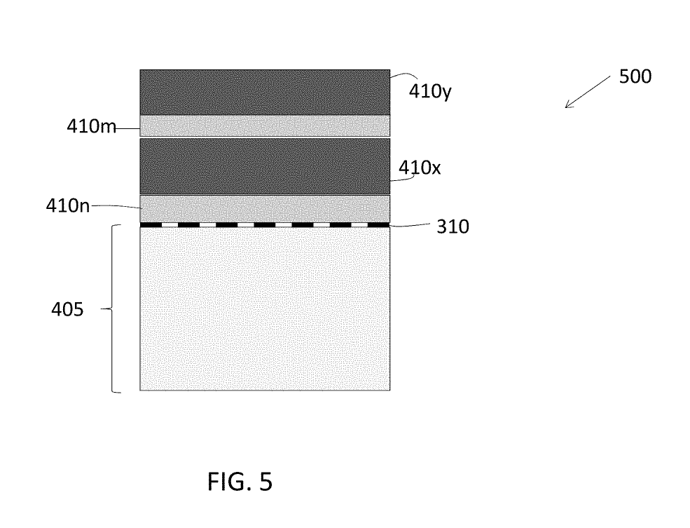

FIG. 5 is a cross-sectional view of an exemplary photovoltaic device 500 according to an embodiment. The exemplary device 500 shown on FIG. 5 includes four optically transparent layers 410n, 410m, 410x, 410y above the metal lines 310 formed on the base layers 405. In general, multiple layers of low and high-dielectric constant materials may be disposed above the metal lines 310 to reflect specific colors. The material that forms layers 410n and 410m may be the same or may be materials within the same column in Table 1 (i.e., may have the same range of index of refraction), and the material that forms layers 410x and 410y may be the same or may be materials within the same column in Table 1. If materials for layers 410n and 410m are selected from one column in Table 1, materials for layers 410x and 410y should be selected from the other column in Table 1. That is, adjacent layers 410 (e.g., layers 410n and 410x) should have different indexes of refraction.

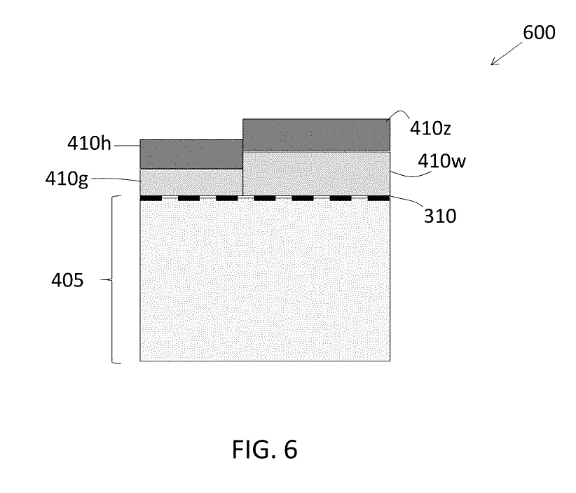

FIG. 6 is a cross-sectional view of an exemplary photovoltaic device 600 according to another embodiment. As FIG. 6 indicates, not only color but also texture (two-dimensional patterning) may be controlled based on controlling the layers 410. That is, one set of layers 410g, 410h may be disposed above a portion of the metal lines 310 while another set of layers 410w, 410z is disposed above another portion of the metal lines 310 on the base layers 405. The total thickness of the set of layers 410g, 410h may differ from the total thickness of the set of layers 410w, 410z to exhibit a two-dimensional pattern on the plane of the visible surface of the photovoltaic device 600. The indexes of refraction of the layers 410g and 410h are different, and the indexes of refraction of the layers 410w and 410z are different. The materials used for layers 410g and 410h may be the same materials used for layers 410w and 410z but with different thicknesses.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method of fabricating a color tunable thin film photovoltaic device, the method comprising:
depositing a layer of a semiconducting compound configured to exhibit a photovoltaic effect;
depositing a buffer layer over the layer of the semiconducting compound;
depositing transparent conducting oxides (TCO) over the buffer layer;
selecting two or more layers of optically transparent materials such that constructive interference among wavelengths reflected by the buffer layer, the TCO, and the two or more layers results in a desired exhibited color; and
depositing the two or more layers of the optically transparent materials above the TCO.

2. The method according to claim 1, wherein the depositing the two or more layers of the optically transparent materials includes selecting a thickness of each of the two or more layers to control the exhibited color.

3. The method according to claim 1, wherein the depositing the two or more layers of the optically transparent materials includes depositing a first set of the two or more layers arranged in a first stacked configuration adjacent to a second set of the two or more layers arranged in a second stacked configuration, the exhibited color of the first set of the two or more layers being different than the exhibited color of the second set of the two or more layers.

4. The method according to claim 3, wherein the depositing the first set of the two or more layers and the depositing the second set of the two or more layers includes selecting a different thickness for the first stacked configuration than the second stacked configuration, the different thickness affecting a texture of the photovoltaic device.

5. The method according to claim 1, further comprising forming metal lines over the TCO configured to carry current generated by the semiconducting compound.

6. The method according to claim 5, wherein the semiconducting compound comprises one of copper-zinc-tin- sulfide (CZTS), copper-zinc-tin-selenium (CZTSe), selenium (Se), copper-zinc-tin-sulfur-selenium (Cu₂ZnSn(SₓSe₁₋ₓ)₄), silver-copper-zinc-tin-selenium AgCZTSe, and silver-zinc-tin-selenium AgZT Se.

7. The method according to claim 1, further comprising depositing a molybdenum layer over soda-lime glass, wherein the depositing the layer of the semiconducting compound is on the molybdenum layer.

8. The method according to claim 6, wherein the depositing the molybdenum layer includes controlling a thickness to 700 nanometers.

9. The method according to claim 1, wherein the depositing the TCO includes depositing two oxide layers.

10. The method according to claim 1, wherein the depositing the two or more layers includes depositing magnesium fluoride (MgF₂), silicon dioxide (SiO₂), cerium fluoride (CeF₃), yttrium fluoride (YF₃), or thorium tetrafluoride (ThF₄) as one of the two or more layers and depositing aluminum oxide (Al₂O₃) or yttrium oxide (Y₂O₃) as another of the two or more layers.

11-20. (canceled)

21. The method according to claim 9, wherein the depositing the two oxide layers includes depositing zinc oxide as one of the two oxide layers.

22. The method according to claim 21, wherein the depositing the two oxide layers includes depositing indium tin oxide as another of the two oxide layers.

23. The method according to claim 5, wherein the forming the metal lines includes forming lines comprised of aluminum.

24. The method according to claim 5, wherein the forming the metal lines includes forming lines comprised of nickel aluminum.

25. The method according to claim 1, wherein the depositing the buffer layer includes depositing a p-type material.

26. The method according to claim 25, wherein the depositing the p-type material includes depositing copper oxide (Cu2O) or zinc telluride (ZnTe).

27. The method according to claim 25, wherein the depositing the layer of the semiconducting compound includes depositing a layer of n-type material.

28. The method according to claim 1, wherein the depositing the buffer layer includes depositing an n-type material.

29. The method according to claim 28, wherein the depositing the p-type material includes depositing cadmium sulfide (CdS).

30. The method according to claim 28, wherein the depositing the layer of the semiconducting compound includes depositing a layer of p-type material.
